(19) United States
(12) Patent Application Publication
(10) Pub. No.: US 2019/0131584 A1
(43) Pub. Date: May 2, 2019

(54) ORGANIC LIGHT-EMITTING DIODE DISPLAY APPARATUS AND METHOD FOR MANUFACTURING THEREOF

(71) Applicant: Yuejun TANG, Wuhan, Hubei (CN)

(72) Inventor: Yuejun TANG, Wuhan, Hubei (CN)

(21) Appl. No.: 15/739,888

(22) PCT Filed: Nov. 15, 2017
(86) PCT No.: PCT/CN2017/111069

§ 371 Date: Dec. 26, 2017

(30) Foreign Application Priority Data
Oct. 31, 2017 (CN) 201711047576.3

(51) Int. Cl. H01L 51/56; H01L 51/52; H01L 27/32; H01L 51/50

(52) U.S. Cl. CPC H01L 51/56; H01L 51/5281; H01L 51/5237; H01L 27/3246; H01L 51/5221; H01L 51/5056; H01L 51/5072; H01L 51/5206; H01L 51/5092

(57) ABSTRACT

An organic light-emitting display apparatus is provided in the present application, including an organic light-emitting display panel, wherein the organic light-emitting display panel includes a substrate, an organic light-emitting device layer disposed on the substrate, an encapsulation layer disposed on the organic light-emitting device layer, and a polarizer, the polarizer is attached on a light emitting surface of the organic light-emitting display panel. The present application further provides a method for manufacturing thereof including the manufacturing of the organic light-emitting display panel, the method for manufacturing the organic light-emitting display panel includes: forming an organic light-emitting device layer on a substrate and attaching a polarizer on an encapsulation layer or a cover glass, respectively. Comparing with the conventional technology, to achieve the fabrication of the corresponding devices respectively, therefore to improve the manufacturing efficiency, reduce manufacturing time and reduce the complexity of the process.

### RELATED APPLICATIONS

The present application is a National Phase of International Application Number PCT/CN2017/111069, filed Nov. 15, 2017, and claims the priority of China Application 201711047576.3, filed Oct. 31, 2017.

### FIELD OF THE DISCLOSURE

The disclosure relates to a display technical field, and more particularly to an organic light-emitting diode display apparatus and method for manufacturing thereof.

### BACKGROUND

At present, organic light-emitting diode, OLED displays as display devices for displaying images have attracted much attention. Unlike the liquid crystal display, LCD devices, OLED displays have a characteristic of self-luminous and do not employ an independent light source, so they can be made thinner and lighter than display devices that employ independent light sources, making it relatively easy to achieve characteristics of flexible, foldable display. In addition, OLED displays have high quality characteristics such as low power consumption, high brightness, high response speed and the like.

However, the manufacture of OLED displays includes a plurality of film layers, such as a Thin Film Transistor, TFT layer, a planarization layer, a pixel defining layer, an organic light-emitting device layer, an encapsulation layer, the encapsulation layer includes an encapsulation cover and/or a thin film encapsulation layer, the OLED display further includes anti-reflective layer of the type such as circular polarizers to reduce the ambient light reflections for outdoor visibility, and even includes cover glass for the function of protection. These manufacturing processes are numerous, complex and need to be improved.

### SUMMARY

In order to overcome the deficiencies of the conventional technology, the present invention provides an organic light-emitting diode display apparatus and a method for manufacturing thereof, so as to improve the manufacturing efficiency and reduce manufacturing time.

The present invention provides an organic light-emitting diode display apparatus, including an organic light-emitting display panel, the organic light-emitting display panel including a substrate, an organic light-emitting device layer disposed on the substrate, an encapsulation layer and a polarizer disposed on the organic light-emitting device layer, wherein the polarizer is attached on the light emitting surface of the organic light-emitting display panel.

Further, the polarizer is disposed on the encapsulation layer and/or a side of the substrate away from the organic light-emitting device layer.

Further, a cover glass is disposed on the encapsulation layer, and the polarizer is disposed on the cover glass.

Further, the encapsulation layer includes at least one layer of an encapsulation thin film and/or an encapsulation cover.

Further, the encapsulation layer includes at least one layer of the encapsulation thin film and the encapsulation cover, and the polarizer is disposed between the encapsulation thin film and the encapsulation cover.

The present invention further provides a first method for manufacturing an organic light-emitting display apparatus, including: manufacturing an organic light-emitting display panel, wherein the method for manufacturing the organic light-emitting display panel includes: forming an organic light-emitting device layer on a substrate and attaching a polarizer on an encapsulation layer, respectively; and performing assembly to the encapsulation layer attached with the polarizer and the substrate with the organic light-emitting device layer.

Further, the encapsulation layer includes at least one layer of an encapsulation thin film and/or an encapsulation cover.

The present invention further provides a second method for manufacturing an organic light-emitting display apparatus, including: manufacturing an organic light-emitting display panel, wherein the method for manufacturing the organic light-emitting display panel includes: forming an encapsulation layer on an organic light-emitting device layer and attaching a polarizer on a cover glass; and performing assembly to the cover glass attached with the polarizer and the organic light-emitting device layer with the encapsulation layer.

The present invention further provides a second method for manufacturing an organic light-emitting display apparatus, including: manufacturing an organic light-emitting display panel, wherein the method for manufacturing the organic light-emitting display panel includes: forming an organic light-emitting device layer on a substrate and attaching a polarizer on an encapsulation layer and a side of the substrate away from the organic light-emitting device layer, respectively; and performing assembly to the encapsulation layer attached with the polarizer and the substrate with the organic light-emitting device layer.

Further, the encapsulation layer includes at least one layer of an encapsulation thin film and/or an encapsulation cover.

Compared with the conventional technology, in the present invention, by attaching the polarizer on the encapsulation layer and/or the cover glass, by fabricating the organic light-emitting device layer and attaching the polarizer on the encapsulation layer and/or the cover glass respectively, and bonding the encapsulation layer and/or the cover glass attached with the polarizer with the substrate with the organic light-emitting device layer to each other in the end, so that the corresponding devices can be separately manufactured, so as to improve the manufacturing efficiency, reduce the manufacturing time and reduce the complexity of the process.

### BRIEF DESCRIPTION OF THE DRAWINGS

FIG. 1-1 is a schematic structural view of the organic light-emitting diode display apparatus of a first embodiment of the present invention;

FIG. 1-2 is a schematic structural view of fabricating an organic light-emitting device layer and an encapsulation layer on a substrate according to the first embodiment of the present invention;

FIG. 1-3 is a schematic structural view of attaching a polarizer on a cover glass according to the first embodiment of the present invention;

FIG. 2-1 is a schematic structural view of the organic light-emitting diode display apparatus of a second embodiment of the present invention;

FIG. 2-2 is a schematic structural view of fabricating the organic light-emitting device layer on the substrate according to the second embodiment of the present invention;

FIG. 2-3 is a schematic structural view of attaching the polarizer on the encapsulation layer according to the second embodiment of the present invention;

FIG. 3-1 is a schematic structural view of the organic light-emitting diode display apparatus of a third embodiment of the present invention;

FIG. 3-2 is a schematic structural view of fabricating the organic light-emitting device layer and the encapsulation thin film on the substrate according to the third embodiment of the present invention;

FIG. 3-3 is a schematic structural view of attaching the polarizer on the cover glass according to the third embodiment of the present invention;

FIG. 4 is a schematic structural view of attaching the polarizer on the substrate according to the fourth embodiment of the present invention;

FIG. 5 is a schematic structural view of the organic light-emitting diode display apparatus of a fifth embodiment of the present invention; and

FIG. 6 is a schematic structural view of the organic light-emitting display panel of the present invention.

### DETAILED DESCRIPTION OF PREFERRED EMBODIMENTS

The present application will be further described in detail with reference to accompanying drawings and preferred embodiments as follows.

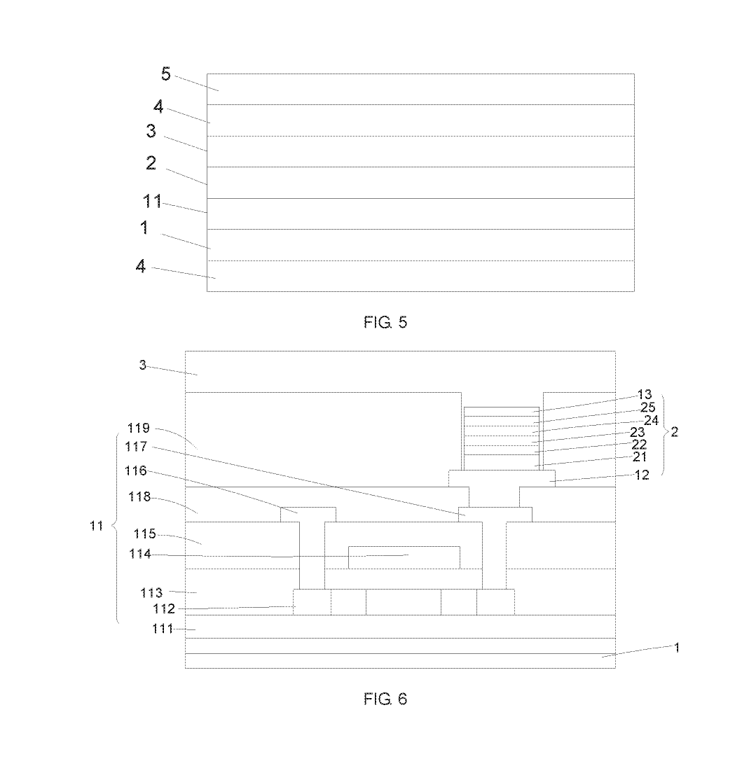

An organic light-emitting diode display apparatus of the present invention includes an organic light-emitting display panel. As shown in FIG. 6, the organic light-emitting display panel at least includes a substrate 1, a thin film transistor layer 11, a pixel defining layer 119, an organic light-emitting device layer 2 and the encapsulation layer 3.

The thin film transistor layer 11 may include a buffer layer 111, an active layer 112, a gate insulating layer 113, a gate electrode 114, an interlayer insulating layer 115, a source electrode 116, a drain electrode 117 and a planarization layer 118 sequentially disposed, but the structure of the thin film transistor of the present invention is not limited thereto, and may be other types of thin film transistors such as an amorphous silicon thin film transistor and a metal oxide thin film transistor.

The organic light-emitting device layer 2 includes an anode 12 and a cathode 13. The anode 12 is in contact with the drain electrode 117 via a through hole; the pixel defining layer 119 is disposed on the planarization layer 118 and the anode 12.

The organic light-emitting device layer 2 further includes a hole injection layer, HIL 21, a hole transport layer, HTL 22, an organic light emitting layer, EML 23, an electron transport layer, ETL 24 and an electron injection layer, EIL 25 sequentially disposed from the anode 12 to the cathode 13; but the organic light-emitting device layer 2 of the present invention is not limited to the structure herein.

The material of the substrate 1 may be glass; metal sheet, it may be polymer material such as polyimide, PI, polycarbonate, PC, polyethersulfone, PES, polyethylene terephthalate, PET, Polyethylene naphthalate, PEN, polyarylate, PAR, or glass fiber reinforced plastic, FRP.

The improvement of the present invention does not lie in the thin film transistor layer and the organic light-emitting device layer. In the present invention, the organic light-emitting display panel can be provided with a top emitting type organic light-emitting display panel, a bottom emitting type organic light-emitting display panel, or a double-sided emitting type organic light-emitting display panel of the conventional technology, since the aforementioned organic light-emitting device layer is the conventional technology, and will not be specifically described herein, the present invention is described in detail below with respect to the improvement.

The polarizer 4 of the present invention is attached to the light-emitting surface of the organic light-emitting display panel. The polarizer 4 is a circular polarizer. The polarizer 4 may be a thin film structure or a sheet structure, which is not limited herein.

The polarizer 4 can be disposed on the encapsulation layer 3 or the cover glass 5, and can be selected according to the actual situation.

In the present invention, the polarizer 4 is a circular polarizer. However, the present invention is not limited thereto. For example, the polarizer 4 may be an anti-reflection layer of other type, the fabricating type of the anti-reflection layer formed on the surface of the encapsulation layer or the protective cover, can also be selected according to the type of the anti-reflection layer, but the assembly of the encapsulation or adhesion/attachment is performed after the two structures are completion respectively.

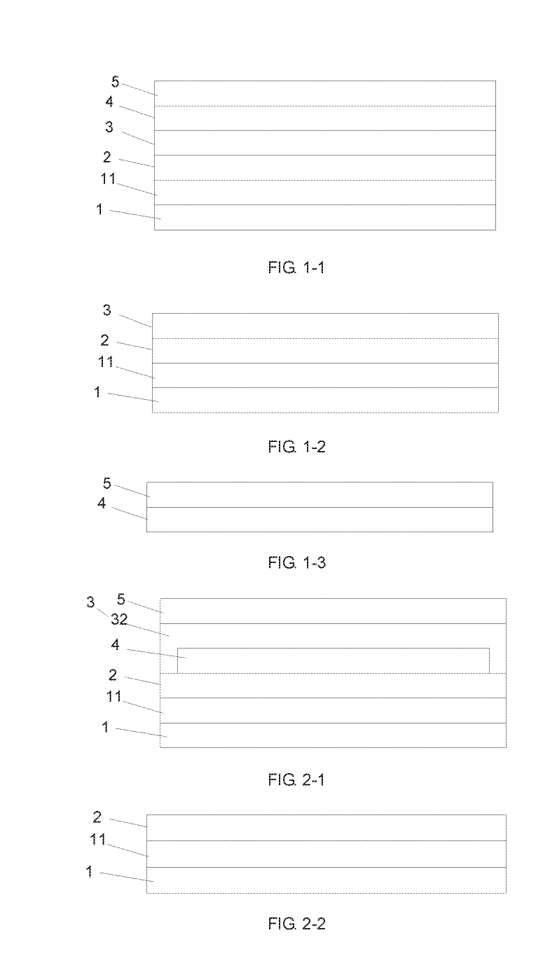

As shown in FIG. 1-1, FIG. 1-1 is a schematic structural view of the organic light-emitting diode display apparatus of a first embodiment of the present invention. In the organic light-emitting diode display apparatus, the organic light-emitting display panel is the top emitting type organic light-emitting display panel, the organic light-emitting display panel is provided with the encapsulation layer 3 on the organic light-emitting device layer 2, the cover glass 5 is provided on the encapsulation layer 3, and the polarizer 4 is attached to the cover glass 5. Specifically, the polarizer 4 is attached to the surface of the cover glass 5 opposite to the encapsulation layer 3. Since the cover glass 5 is provided here, therefore the encapsulation layer 3 can use at least one layer of encapsulation thin film 31.

The encapsulation thin film 31 is a single layer or a plurality of inorganic material layers. It can also be an alternately lamination of a plurality of inorganic material layers and organic material layers.

The method for manufacturing the first embodiment of the present invention includes the following steps:

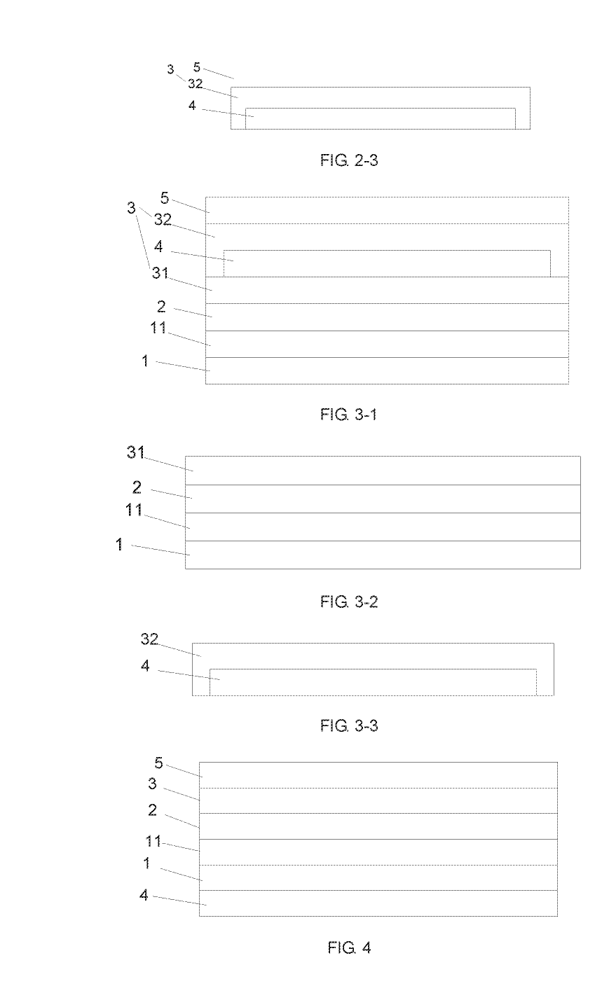

As shown in FIG. 1-2, forming the thin film transistor layer 11, the organic light-emitting device layer 2 and the encapsulation layer 3 on the substrate 1 by using the conventional technology.

And as shown in FIGS. 1-3, attaching the polarizer 4 to the cover glass 5; specifically, a mark structure for alignment (not shown in the FIG.) may be formed on the cover glass. The mark structure is a conventional technology, and is not specifically limited here, the polarizer 4 is aligned with the substrate 1 having the encapsulation layer 3 by the mark structure.

As shown in FIG. 1-1, performing the assembly to the cover glass 5 attached with the polarizer 4 and the substrate with the encapsulation layer 3, the assembly here may be performed by adhering or attaching.

In the first embodiment, the step of forming the thin film transistor layer 11, the organic light-emitting device layer 2 and the encapsulation layer 3 on the substrate 1 and the step of attaching the polarizer 4 on the cover glass 5 may be performed separately and simultaneously, it may be performed at different times respectively, which is not specific limited herein.

In the first embodiment, the thin-film transistor layer 11, the organic light-emitting device layer 2, the encapsulation layer 3, the polarizer 4, and the cover glass 5 need not be sequentially formed on the substrate 1 according to the procedure, instead fabricating separately, the thin film transistor layer 11, the organic light-emitting device layer 2 and the encapsulation layer 3 are formed on the substrate by adapting the conventional manufacturing method. In addition, the polarizer 4 is attached/adhered to the cover glass 5, so that the manufacturing process is separated, to improve the manufacturing efficiency of the organic light-emitting display apparatus.

In the first embodiment, the polarizer 4 is attached on one surface of the cover glass 5 opposite to the encapsulation layer 3, and the attachment of the polarizer 4 can adopt the conventional technology, which is not limited herein.

As shown in FIG. 2-1, FIG. 2-1 is a schematic structural view of the organic light-emitting diode display apparatus of a second embodiment of the present invention. In the organic light-emitting diode display apparatus, the organic light-emitting display panel is the top emitting type organic light-emitting display panel, the organic light-emitting display panel is provided with the encapsulation layer 3 on the organic light-emitting device layer 2, the encapsulation layer 3 includes an encapsulation cover 32, the polarizer 4 is attached to the encapsulation cover 32. Specifically, the polarizer 4 is attached to the surface of the encapsulation cover 32 opposite to the organic light-emitting device layer 2.

In the second embodiment, a surface of the encapsulation cover 32 away from the polarizer 4 can be provided with the cover glass 5.

The method for manufacturing the second embodiment of the present invention includes the following steps:

As shown in FIG. 2-2, forming the thin film transistor layer 11 and the organic light-emitting device layer 2 on the substrate 1 by using the conventional technology.

And as shown in FIGS. 2-3, attaching the polarizer 4 to the encapsulation layer 3; specifically, the encapsulation layer 3 includes the encapsulation cover 32, the polarizer 4 is attached to the surface of the encapsulation cover 32 opposite to the organic light-emitting device layer 2, of course, the mark structure for alignment (not shown in the FIG.) may be formed on the encapsulation cover 32. The mark structure is a conventional technology, and is not specifically limited here, the polarizer 4 is aligned with the substrate 1 having the organic light-emitting device layer 2 by the mark structure.

As shown in FIG. 2-1, performing the assembly to the encapsulation layer 3 attached with the polarizer 4 and the substrate with the organic light-emitting device layer 2, the assembly here can be performed by an encapsulant, which is not limited herein.

Before or after attaching the polarizer 4 to the encapsulation layer 3, the cover glass 5 may also be attached to the surface of the encapsulation layer 3 away from the polarizer 4, which is not limited herein.

In the second embodiment, the thin-film transistor layer 11, the organic light-emitting device layer 2, the encapsulation layer 3 and the polarizer 4 need not be sequentially formed on the substrate 1 according to the procedure, instead to fabricate separately, the thin film transistor layer 11 and the organic light-emitting device layer 2 are formed on the substrate by adapting the conventional manufacturing method. In addition, the polarizer 4 is fabricated on the encapsulation layer 3, so that the manufacturing process is separated, to improve the manufacturing efficiency of the organic light-emitting display apparatus.

As shown in FIG. 3-1, FIG. 3-1 is a schematic structural view of the organic light-emitting diode display apparatus of a third embodiment of the present invention. In the organic light-emitting diode display apparatus, the organic light-emitting display panel is the top emitting type organic light-emitting display panel, the organic light-emitting display panel is provided with the encapsulation layer 3 on the organic light-emitting device layer 2, the encapsulation layer 3 includes the encapsulation thin film 31 and the encapsulation cover 32, the encapsulation thin film 31 is disposed on the organic light-emitting device layer 2, the polarizer 4 is attached to one surface of the encapsulation cover 32 opposite to the encapsulation thin film 31.

In the third embodiment, the surface of the encapsulation cover 32 away from the polarizer 4 can be provided with the cover glass 5.

The method for manufacturing the third embodiment of the present invention includes the following steps:

As shown in FIG. 3-2, forming the thin film transistor layer 11, the organic light-emitting device layer 2 and the encapsulation thin film 31 the on the substrate 1 by using the conventional technology.

And as shown in FIGS. 3-3, attaching the polarizer 4 to the encapsulation cover 32; specifically, the mark structure for alignment (not shown in the FIG.) may be formed on the encapsulation cover 32. The mark structure is a conventional technology, and is not specifically limited here, the polarizer 4 is aligned with the substrate 1 having the organic light-emitting device layer 2 and the encapsulation thin film 31 by the mark structure.

In the third embodiment, the encapsulation layer 3 is fabricated by the way of separately fabrication.

As shown in FIG. 3-1, performing the assembly to the encapsulation cover 32 attached with the polarizer 4 and the substrate with the organic light-emitting device layer 2 and the encapsulation thin film 31, the assembly here can be performed by the ways of attached or adhered or perform the encapsulation by the encapsulant.

Before or after attaching the polarizer 4 to the encapsulation cover 32, the cover glass 5 may also be attached to the surface of the encapsulation cover 32 away from the polarizer 4, which is not limited herein.

The encapsulation thin film 31 is a single layer or a plurality of inorganic material layers. It can also be an alternately lamination of a plurality of inorganic material layers and organic material layers.

In the third embodiment, the thin-film transistor layer 11, the organic light-emitting device layer 2, the encapsulation layer 3 and the polarizer 4 need not be sequentially formed on the substrate 1 according to the procedure, instead to fabricate separately, the thin film transistor layer 11, the organic light-emitting device layer 2, and the encapsulation thin film 31 are formed on the substrate by adapting the conventional manufacturing method. In addition, the polarizer 4 is fabricated on the encapsulation cover 32, so that the manufacturing process is separated, to improve the manufacturing efficiency of the organic light-emitting display apparatus.

As shown in FIG. 4, the organic light-emitting display panel of the organic light-emitting diode display apparatus in the fourth embodiment is a bottom emitting type organic light-emitting display panel, the structure is the conventional technology, and will not be described in detail here. It should be noticed that, the polarizer 4 herein is attached to the light emitting surface of the organic light-emitting diode display panel, specifically, the polarizer 4 is attached to a surface of the substrate 1 away from the carrying the thin film transistor layer 11 and the organic light-emitting device layer 2.

The method for manufacturing the fourth embodiment of the present invention includes the following steps:

As shown in FIG. 1-2, forming the thin film transistor layer 11, the organic light-emitting device layer 2 and the encapsulation layer 3 on the substrate 1 by using the conventional technology.

And as shown in FIG. 4, the polarizer 4 is attached on the surface of the substrate 1 away from the thin film transistor layer 11 and the organic light-emitting device layer 2; specifically, the mark structure for alignment (not shown in the FIG.) may be formed on the substrate 1, the mark structure is a conventional technology, and is not specifically limited here, the polarizer 4 is aligned by the mark structure.

As shown in FIG. 5, FIG. 5 is a schematic structural view of the organic light-emitting diode display apparatus of a fifth embodiment of the present invention, the organic light-emitting display panel of the organic light-emitting diode display apparatus is a transparent organic light-emitting display panel or the double-sided emitting type organic light-emitting display panel, the disposing position of the polarizer 4 herein is the light emitting surface of the organic light-emitting diode display panel, specifically, the arrangement of the polarizer 4 can be performed by using the arrangement structures and the method for manufacturing thereof of the polarizers 4 in the first to third embodiments, and will not be described in detail herein. As shown in the figures, the polarizer 4 is disposed on the surface of the substrate 1 away from the thin film transistor layer 11 and on the encapsulation layer 3.

In the present invention, it is not necessary to sequentially fabricate or attach/adhere the organic light-emitting device layer 2, the encapsulation layer, the polarizer and the cover glass and the like on the substrate, the fabrication of the two structures of the present application can be performed separately, and then performing the encapsulation or adhering/attaching process to assembly, to enhance the fabrication of the OLE© display apparatus and fabrication efficiency.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. An organic light-emitting display apparatus, comprising an organic light-emitting display panel, wherein the organic light-emitting display panel comprises a substrate, an organic light-emitting device layer disposed on the substrate, an encapsulation layer disposed on the organic light-emitting device layer, and a polarizer, the polarizer is attached on a light emitting surface of the organic light-emitting display panel.

2. The organic light-emitting display apparatus according to claim 1, wherein the polarizer is disposed on the encapsulation layer or a side of the substrate away from the organic light-emitting device layer.

3. The organic light-emitting display apparatus according to claim 1, wherein the polarizer is disposed the encapsulation layer and a side of the substrate away from the organic light-emitting device layer.

4. The organic light-emitting display apparatus according to claim 1, wherein a cover glass is disposed on the encapsulation layer, and the polarizer is disposed on the cover glass.

5. The organic light-emitting display apparatus according to claim 1, wherein the encapsulation layer comprises at least one layer of an encapsulation thin film and an encapsulation cover.

6. The organic light-emitting display apparatus according to claim 1, wherein the encapsulation layer comprises at least one layer of an encapsulation thin film or an encapsulation cover.

7. The organic light-emitting display apparatus according to claim 2, wherein the encapsulation layer comprises at least one layer of an encapsulation thin film and an encapsulation cover.

8. The organic light-emitting display apparatus according to claim 2, wherein the encapsulation layer comprises at least one layer of an encapsulation thin film or an encapsulation cover.

9. The organic light-emitting display apparatus according to claim 3, wherein the encapsulation layer comprises at least one layer of an encapsulation thin film or an encapsulation cover.

10. The organic light-emitting display apparatus according to claim 5, wherein the encapsulation layer comprises at least one layer of the encapsulation thin film and the encapsulation cover, and the polarizer is disposed between the encapsulation thin film and the encapsulation cover.

11. The organic light-emitting display apparatus according to claim 6, wherein the encapsulation layer comprises at least one layer of the encapsulation thin film and the encapsulation cover, and the polarizer is disposed between the encapsulation thin film and the encapsulation cover.

12. The organic light-emitting display apparatus according to claim 7, wherein the encapsulation layer comprises at least one layer of the encapsulation thin film and the encapsulation cover, and the polarizer is disposed between the encapsulation thin film and the encapsulation cover.

13. The organic light-emitting display apparatus according to claim 8, wherein the encapsulation layer comprises at least one layer of the encapsulation thin film and the encapsulation cover, and the polarizer is disposed between the encapsulation thin film and the encapsulation cover.

14. A method for manufacturing an organic light-emitting display apparatus, comprising: manufacturing an organic light-emitting display panel, wherein the method for manufacturing the organic light-emitting display panel comprises:
forming an organic light-emitting device layer on a substrate and attaching a polarizer on an encapsulation layer, respectively; and
performing assembly to the encapsulation layer attached with the polarizer and the substrate with the organic light-emitting device layer.

15. The method for manufacturing the organic light-emitting display apparatus according to claim 14, wherein the encapsulation layer comprises at least one layer of an encapsulation thin film and an encapsulation cover.

16. The method for manufacturing the organic light-emitting display apparatus according to claim 14, wherein the encapsulation layer comprises at least one layer of an encapsulation thin film or an encapsulation cover.

17. A method for manufacturing an organic light-emitting display apparatus, comprising: manufacturing an organic light-emitting display panel, wherein the method for manufacturing the organic light-emitting display panel comprises:
forming an encapsulation layer on an organic light-emitting device layer and attaching a polarizer on a cover glass; and
performing assembly to the cover glass attached with the polarizer and a substrate with the encapsulation layer.

18. A method for manufacturing an organic light-emitting display apparatus, comprising: manufacturing an organic light-emitting display panel, wherein the method for manufacturing the organic light-emitting display panel comprises:
forming an organic light-emitting device layer on a substrate and attaching a polarizer on an encapsulation layer and a side of the substrate away from the organic light-emitting device layer, respectively; and
performing assembly to the encapsulation layer attached with the polarizer and the substrate with the organic light-emitting device layer.

19. The method for manufacturing the organic light-emitting display apparatus according to claim 18, wherein the encapsulation layer comprises at least one layer of an encapsulation thin film and an encapsulation cover.

20. The method for manufacturing the organic light-emitting display apparatus according to claim 18, wherein the encapsulation layer comprises at least one layer of an encapsulation thin film or an encapsulation cover.
